(19) United States
(12) Patent Application Publication
(10) Pub. No.: US 2015/0097778 A1
(43) Pub. Date: Apr. 9, 2015

(54) OPTICAL SENSING MODULE, LASER POINTING DEVICE USING THE SAME AND THE FABRICATING METHOD THEREOF

(71) Applicants: YUN-SHAN CHANG, SAN JOSE, CA (US); DA-WEI LIN, NEW TAIPEI CITY (TW)

(72) Inventor: YUN-SHAN CHANG, SAN JOSE, CA (US)

(73) Assignees: DA-WEI LIN, NEW TAIPEI CITY (TW); YUN-SHAN CHANG, SAN JONE, CA (US)

(21) Appl. No.: 14/049,424

(22) Filed: Oct. 9, 2013

(51) Int. Cl. G06F 3/0354; H01L 25/16

(52) U.S. Cl. CPC G06F 3/0354; H01L 25/167
USPC 345/166; 438/25

(57) ABSTRACT

An optical sensing module includes an image sensing element having an optical sensor array and at least a control unit. A light emitting chip provides a coherent light. The light is reflected from an outside surface and to be received by the optical sensor array. A substrate is mounted with the image sensing element and the light emitting chip. A cover is mounted on the substrate to cover the image sensing element and the light emitting chip, and the cover includes a first light-transmitting portion on the transmission path of the light. The optical sensing module is disposed on a base having a second light-transmitting portion on the transmission path of the light.

### BACKGROUND OF THE INVENTION

1. Field of the Invention

The present disclosure relates to an optical sensing module, a laser pointing device using the same and a fabricating method of the optical sensing module, and more particularly, to an optical sensing module having an image sensing element and a light emitting chip, and the fabricating method of the same.

2. Description of Related Art

In the technology of present optical mouse having an optical sensing module, the optical sensing module mainly includes an optical lens, an image sensor, and a light source. The light source commonly may be a Light Emitting Diode (LED) or a laser light source such as Laser Diode (LD). When the optical mouse is in operation, the light emitted from the light source (such as LED) is spread and enters the lens, and then go through a series of reflection and refraction in the optical path.

In the main optical path, the light passes through the lens and projects onto an object surface, such as a desktop or a surface of an optical mouse pad. Then, the light reflects off the object surface and passes through the converging portion of the lens and is captured by the image sensing element. The moving distance and direction of the optical mouse can be obtained through the calculation of the digital signal processing components of the optical mouse.

Typically, the TO (Transistor Outline Package) or the lamp package is applied in the packaging method for the light emitting chip of the optical sensing module in the conventional optical mouse devices. Refer to FIG. 1, which shows a conventional optical sensing module 30 applying a VCSEL Laser 32 (Vertical-Cavity Surface-Emitting Laser) as a light source. The VCSEL Laser 32 is disposed on a printed circuit board 34. An image sensing element 36 is disposed on the inner surface of the fixing seat 38. An optical lens member 40 is disposed between the VCSEL Laser 32 and the image sensing element 36. The optical lens member 40 can converge the light beam 42 emitted by the VCSEL Laser 32 and transmit the light beam 42 to the desktop 44. The converging portion 35 of the optical lens member 40 also focuses the light beam 42 reflected from the desktop 44 on the image sensing element 36.

Accordingly, it is possible to reduce the energy of the light beam 42 because of the light loss of the entire optical path. The light loss is caused by the bulkier packaging size and longer optical path owing to the additional fastening or attachment structure for the fixing of the optical lens member 40. Also, the light loss is caused by a longer optical path of the light beam 42 while traveling through multiple reflections and refractions between the VCSEL Laser 32 and the image sensing element 36.

Therefore, in order to prevent weak signals owing to the energy loss of light beam 42 received by the image sensing element 36 from affecting the detection of the image sensing element 36, the converging portion 35 is disposed on the optical lens member 40 to enhance the optical signal strength, and the VCSEL Laser 32 does not have too low power.

### SUMMARY OF THE INVENTION

The present disclosure is to provide an optical sensing module, a laser pointing device using the same and a fabricating method of the optical sensing module, wherein the optical sensing module can effectively reduce the energy loss of the light.

According to one embodiment of the present disclosure, there is provided an optical sensing module, including an image sensing element, a light emitting chip, a substrate, and a cover. The image sensing element including an optical sensor array and at least a control unit. The light emitting chip for emitting a coherent light beam which is being projected on an external surface. The optical sensor array receives the coherent light beam reflected off the external surface. A substrate is electrically mounted with the image sensing element and the light emitting chip thereon. A cover is disposed on the substrate and covers the image sensing element and the light emitting chip. The cover includes a first light-transmitting portion formed on the transmission path of the light beam.

According to another embodiment of the present disclosure, there is provided an optical sensing module, including an image sensing element, a light emitting chip, a substrate, and a cover. The image sensing element including an optical sensor array and at least a control unit. The light emitting chip is used for emitting a coherent light beam being projected onto an external surface and reflected back to be received by the optical sensor array. The light emitting chip and the image sensing element are being integrated into an integrated circuit (IC). The substrate having the integrated circuit electrically mounted thereon. The cover is disposed on the substrate and covers the integrated circuit. The cover including a first light-transmitting portion formed on the transmission path of the light beam.

Accordingly, the present disclosure provides a highly integrated optical sensing module. More specifically, the image sensing element may be a CMOS (complementary metal-oxide semiconductor) image sensor. The light emitting chip and the image sensing element are integrated into the integrated circuit (IC). The integrated circuit is electrically mounted to a surface of the substrate applying a Chip-on-Board (COB) process. In accordance with one aspect of the present disclosure, the light emitting chip and the image sensing element are separately and adjacently disposed on the same surface of the substrate applying the COB process. The image sensing element may be a CMOS image sensor. Therefore, the light emitting chip and the image sensing element are integrated to form a CMOS image sensor package (CIS package).

Accordingly, the optical sensing module includes a cover which is disposed on the substrate and covers the CMOS image sensor package. The cover includes a first light-transmitting portion formed on the transmission path of the light beam for the passing of the light beam. The cover may provide the protection and dustproof function for the die attach structure and wire bonding of the CMOS image sensor package.

In another embodiment of the present disclosure, a laser pointing device including the optical sensing module according to the present disclosure is provided. The laser pointing device includes an image sensing element, a light emitting chip, a substrate, a cover, and a base. The optical sensing module is fixedly attached to the base. In one embodiment, the laser pointing device may be an optical mouse, includes the base which is formed on the bottom surface of the optical mouse body. The substrate is configured to mount and electrically connect to the image sensing element and the light emitting chip thereon. The light emitting chip is used for providing a coherent light beam. The cover is disposed on the substrate and covers the image sensing element and the light emitting chip mounted on the substrate. The cover having a first light-transmitting portion formed thereon corresponding to the image sensing element, the light emitting chip and the transmission path of the light beam. The base having a second light-transmitting portion formed thereon corresponding to the transmission path of the light beam.

In another embodiment of the present disclosure, there us provided a method of fabricating the optical sensing module, including the steps of: performing a wafer mount process of the sensor wafer (wafer containing the integrated image sensor IC); providing a sensor wafer chip probing process, which includes a chip probing (wafer probe) by using a probe card as well as a light testing to test the electrical characteristics of a sensor wafer; Grinding the sensor wafer to appropriate sensor die and wire bond thickness; performing the tapping, sawing and de-tapping process (a plurality of image sensing elements can be removed or peeled away from the tap) of the sensor wafer to form a plurality of image sensing elements. In the present disclosure, the image sensing element may be an image sensor integrated circuit (image sensor IC); applying a die attach process to mount a laser diode die and an image sensing element on a substrate, wherein the laser diode die is mounted close to the image sensing element. After the die attach process, the image sensing element, the laser diode die and the substrate are electrically connected. In another embodiment of the present disclosure, the laser diode die can be mounted on the image sensing element before mounting the image sensing element on the substrate. However, the die attach process order is not limited to this. Next, wire bond the image sensing element and the laser diode die after a plasma cleaning process; providing a cover to be disposed on the substrate and over the image sensing element and the laser diode die.

Accordingly, the additional optical lens may not be provided in the present disclosure, and therefore the production cost can be reduced. Moreover, the dimension of the optical sensing module may be reduced by the reduction of the optical path length from the optical sensing module to the light reflective outside surface. Therefore, the light transmission losses in the entire optical path can be reduced, and the sensitivity of the optical sensing module may be increased.

In order to further the understanding regarding the present invention, the following embodiments are provided along with illustrations to facilitate the disclosure of the present invention.

### BRIEF DESCRIPTION OF THE DRAWINGS

FIG. 1 shows a schematic cross-section view illustrating a conventional optical mouse;

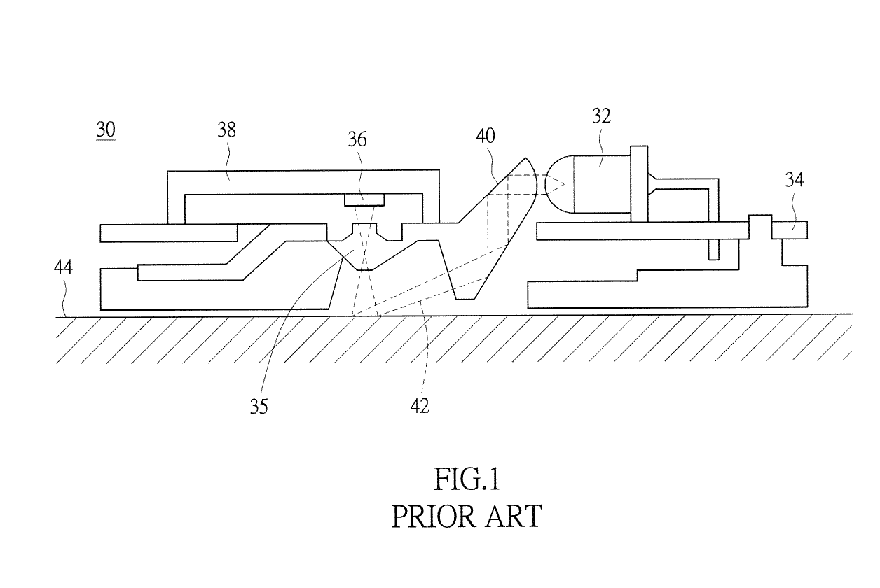

FIG. 2 shows a schematic structural diagram of an optical sensing module according to a first embodiment;

FIG. 3 shows a schematic structural diagram of an optical sensing module according to a second embodiment;

FIG. 4 schematic shows an optical sensing module for a laser pointing device according to the present disclosure;

FIG. 5 shows a schematic structural diagram of an optical sensor array according to a third embodiment; and

FIG. 6 shows a schematic representation of the manufacturing process of the optical sensing module according to the present disclosure.

### DETAILED DESCRIPTION OF THE PREFERRED EMBODIMENTS

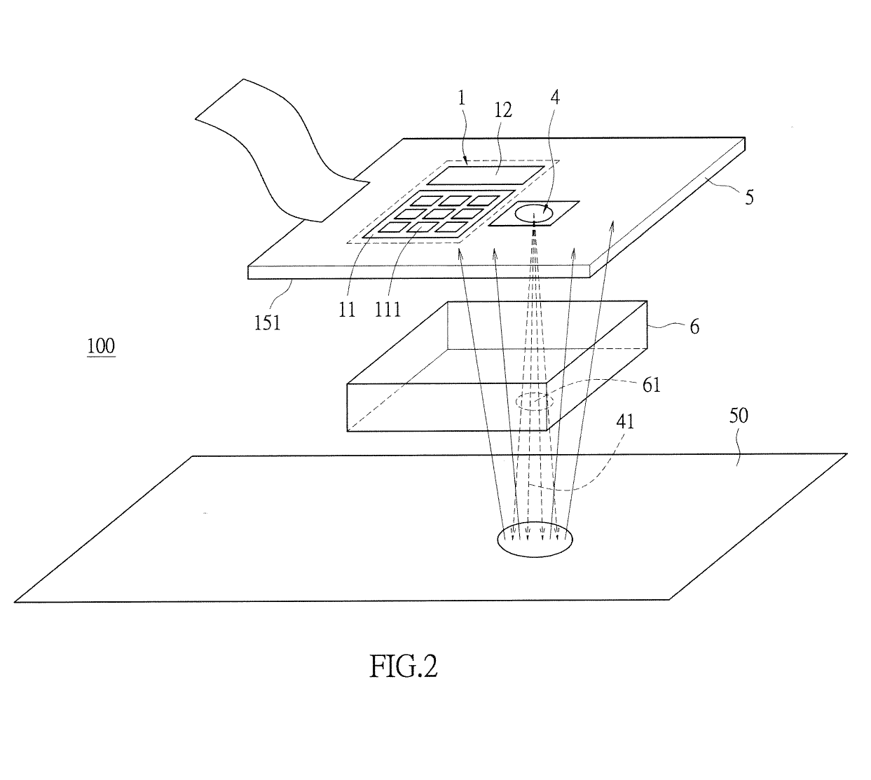

FIG. 2 shows a schematic structural diagram of an optical sensing module according to a first embodiment. Refer to FIG. 2. An optical sensing module 100 includes an image sensing element 1, a light emitting chip 4, a substrate 5, and a cover 6. The substrate 5 has a lower surface 151 which is facing an external reflective external surface 50. The image sensing element 1, the light emitting chip 4, and the cover 6 are disposed on the lower surface 151 of the substrate 5.

The image sensing element 1 includes an optical sensor array 11 and at least a control unit 12. The optical sensor array 11 may be formed of such as, but no limited to a plurality of Charge-Coupled Device (CCD) or Complementary-metal-oxide Semiconductor (CMOS) elements.

The control unit 12 including but not limited to the number and types of the following components, such as analog front-end circuits, A/D converters, readout control circuits, timing and data processing circuitries, laser diode (LD) drivers with smart power sleep mode and auto exposure timing control, SMD (Surface Mounted Device) decoupling capacitors and so on.

The light emitting chip 4 may be a semiconductor chip for producing a coherent light beam 41. The light emitting chip 4 can be a semiconductor chip or die, such as a laser diode die. In this embodiment, the light emitting chip 4 is a laser diode die (LD die) which provides the coherent light beam 41.

The cover 6 is fixedly attached on the lower surface 151 of the substrate 5 by any suitable method known in the art, including, but not limited to, adhering, mechanical fastening, and so on. The cover 6 covers the image sensing element 1 and the light emitting chip 4 mounted on the substrate 5. A first light-transmitting portion 61 is formed on the cover 6 corresponding to the transmission path of the light beam 41. In accordance with the above description of the present disclosure, the light emitting chip 4 provides a light beam 41 projecting onto an external surface 50, and the light beam 41 is reflected from the external surface 5 and to be received by the image sensing element 1. The light beam 41 reflected by the external surface 50 is sensed by the optical sensor array 11 of the image sensing element 1. Therefore, the image captured by the image sensing element 1 may be change according to the movement of the optical sensing module 100 under operation by the user.

The first light-transmitting portion 61 of the cover 6 may be, in one embodiment, patterned to form an opening located corresponding to the image sensing element 1 and the light emitting chip 4 mounted on the substrate 5, and exposing the image sensing element 1 and the light emitting chip 4. The opening provides a light-filtering effect which screens the refracted, reflected, and scattered light beam 41 reflected from the external surface 50.

Therefore, through the installation of the cover 6, which may exclude the unnecessary interferences caused by the reflections and the ambient light, as a result, improve the light collection efficiency of the image sensing element 1. The cover 6 is also arranged to provide dust-proof and protection mechanism for the die attachment and wire bonding of the image sensing element 1 and the light emitting chip 4.

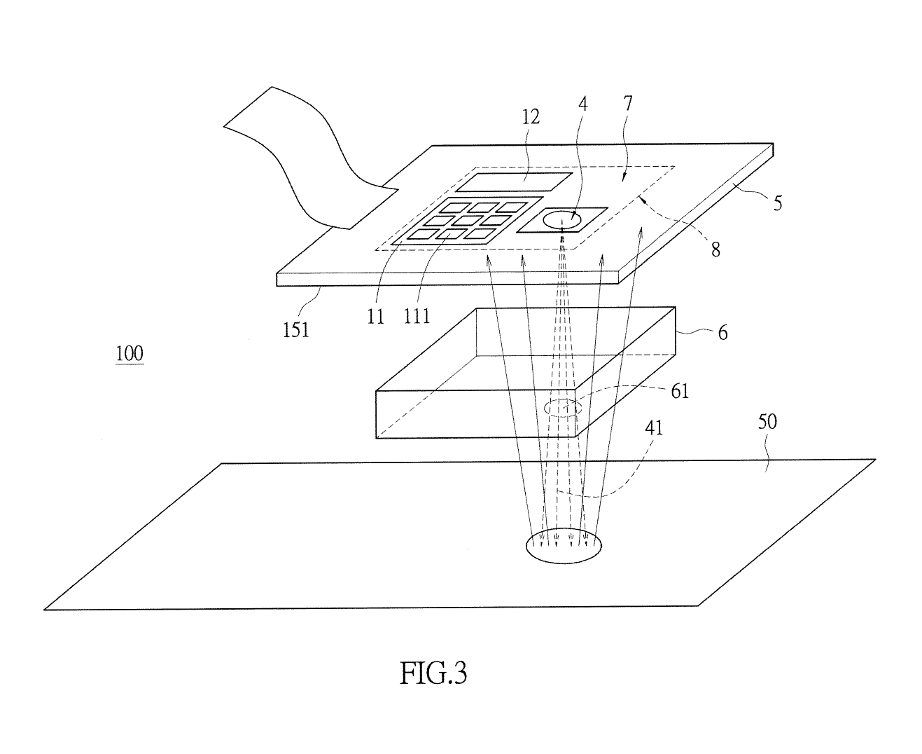

FIG. 3 shows a schematic structural diagram of an optical sensing module according to a second embodiment of the present disclosure. The differences between the first embodiment and the second embodiment of the present disclosure reside in the configuration of the light emitting chip 4 and the image sensing element 1. As shown in FIG. 3, the light emitting chip 4 and the image sensing element 1 in FIG. 2 are integrated into an integrated circuit 7. To be more specific, the integrated circuit 7 may be an Optoelectronic Integrated Circuit (OEIC) includes an optical sensor array 11, a light emitting chip 4, and at least a control unit 12 disposing on a semiconductor substrate 8. The semiconductor substrate 8 is electrically bonded to the lower surface 151 of the substrate 5. The optical sensor array 11, the control unit 12 and the light emitting chip 4 are integrated in the same integrated circuit 7 device. In this way, the reaction rate being affected by the discrete effect of the separating element may be reduced. The miniaturization of the optical sensing module 100 can be further promoted because of the integration.

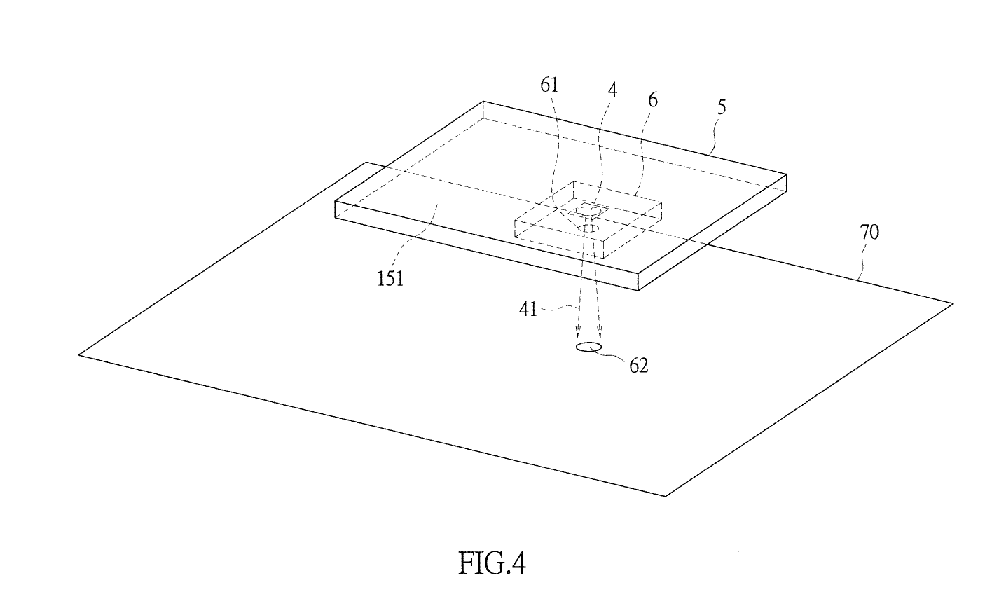

FIG. 4 schematic shows an optical sensing module for a laser pointing device according to the present disclosure. When the optical sensing module 100 of the present disclosure is applied to a laser pointing device, such as an optical mouse (not shown), the optical sensing module 100 is mounted on the base 70 located at the bottom surface of the optical mouse. Refer to FIG. 2 and FIG. 4, the light emitting chip 4 may be a laser diode die and produces a coherent light beam 41 that project onto and reflect back from an external surface 50, and finally to be received by the optical sensor array 11. The base 70 includes a second light-transmitting portion 62 formed thereon. The second light-transmitting portion 62 is arranged corresponding to a transmission path of the light beam 41, wherein the second light-transmitting portion 62 may be an opening.

In this embodiment, a light beam 41 which is emitted by the light emitting chip 4, sequentially travels through the first light-transmitting portion 61 of the cover 6, the second light-transmitting portion 62 of the base 70, and projects onto an external surface 50. The light beam 41 which is reflected by the external surface 50 sequentially travels through the second light-transmitting portion 62 of the base 70, the first light-transmitting portion 61 of the cover piece 6, and finally reaches to the optical sensor array 11 of the image sensing element 1. Therefore, the opening formed on the second light-transmitting portion 62 may provide the light-filtering effect which may exclude the unnecessary interferences caused by the reflections and the ambient light, as a result, improve the light collection efficiency of the image sensing element 1. Accordingly, the influence of the sensitivity of the optical sensor array 11 may be decreased.

As mentioned above, according to the present disclosure, the second light-transmitting portion 62 may be used to provide a spatial filtering effect. The light beam 41 emitted from the light emitting chip 4 may be scattered by the particles in the air or by the defects of the optical element. Such light interferences are collectively referred to as spatial noises. According to the present disclosure, through adjusting the ratio of the diameter of the second light-transmitting portion 62 to the wavelength of the light beam 41, and/or through adjusting the distance between the second light-transmitting portion 62 and the light emitting chip 4, the second light-transmitting portion 62 may be used to remove or reduce the undesirable spatial noises caused by the scattering light. In one embodiment, the ratio of the diameter of the second light-transmitting portion 62 to the wavelength of the light beam 41 is greater than 10.

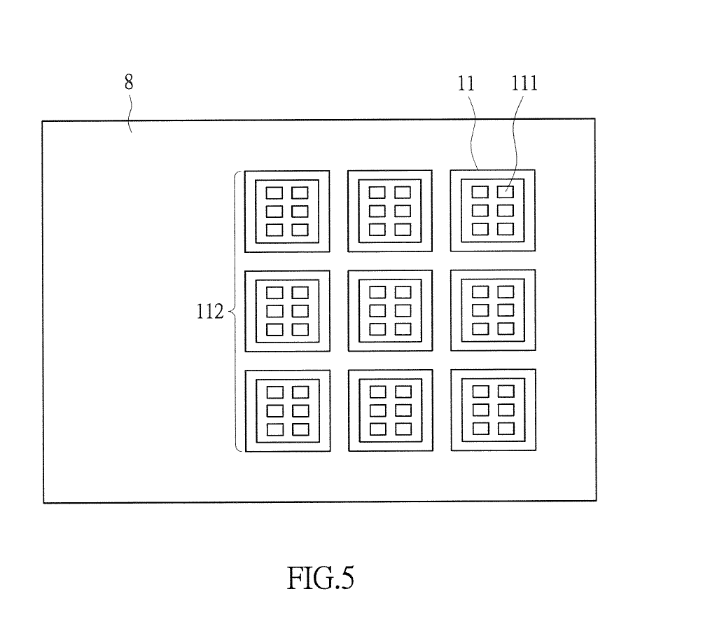

FIG. 5 shows a schematic structural diagram of an optical sensor array according to a third embodiment. Referring to FIG. 5, an optical sensor array 11, which is disposed on the semiconductor substrate 8, includes a plurality of photosensitive elements 111. The sensor array 112 includes a plurality of optical sensor array 11 arranged in a sensor array matrix having columns and rows. The plurality of photosensitive elements 111 may be a solid state image sensor, each of the photosensitive elements 111 including either a photogate, photodiode (whether of the pinned, partially pinned, or unpinned variety), or Charge-Coupled Device (CCD) and the like overlying the semiconductor substrate 8.

According to the third embodiment of the present disclosure, the photosensitive elements 111 is a photodiode, and particularly to a photodiode-type CMOS imager manufactured by the standard Complementary Metal Oxide Semiconductor (CMOS) technology and process, and without the need to create a customized mask layout for the photosensitive elements 111.

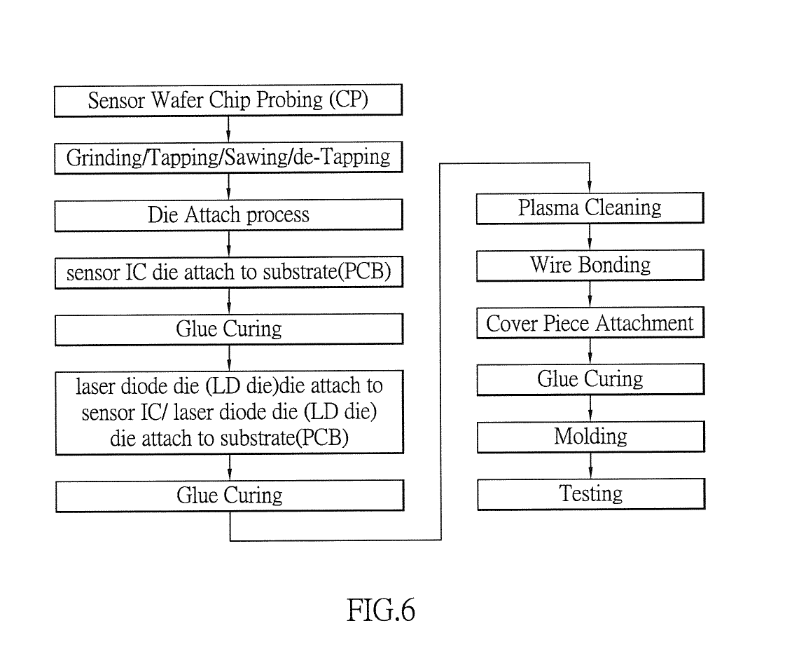

FIG. 6 shows a schematic flow chart of the manufacturing process of the optical sensing module 100 according to the present disclosure. Referring to FIG. 6, which schematic shows a method of manufacturing an optical sensing module mainly includes the steps of providing a sensor wafer chip probing test which includes a chip probing by a probe card as well as a light testing process to test the electrical characteristics of a sensor wafer. Grinding the sensor wafer to sensor die and wire bond thickness; performing the tapping, sawing and de-tapping (peeling from the tap) process of the sensor wafer to form a plurality of image sensing elements, wherein the image sensing element may be an image sensor semiconductor integrated circuit (image sensor IC); applying a die attach process to mount the image sensing element on a substrate, which may be a printed circuit board (PCB); mounting a light emitting chip, which may be a laser diode die on the substrate in close proximity to the said image sensing element. In another embodiment (not shown in the figure), the light emitting chip is directly mounted on a semiconductor substrate where the image sensing element is disposed on, and to form an integrated circuit, therefore, the image sensing element and the light emitting chip are integrated in the same integrated circuit, and the integrated circuit is electrically bonded to the substrate; wire bonding the image sensing element and the light emitting chip after surface cleaning using the plasma; providing a cover, adhering or mechanical fastening the cover on the substrate and covering the image sensing element and the light emitting chip.

As shown in FIG. 6, the die attach process may be performed applying a standard Chip on Board (COB) technology, such as, but not limited to pin through hole, surface mount, wire bonding, or tape automated bonding (TAB).

As described above, according to the present disclosure, the optical sensing module have the advantages of:

Through applying the optical sensing module to a laser pointing device, such as a laser optical mouse. That is, by integrating both the image sensing element and the light emitting chip into the same integrated circuit, and electrically connecting the integrated circuit to the substrate including a cover disposed thereon to cover the image sensing element and the light emitting chip. In this way, both the light energy loss in the entire optical path and the dimension of the optical sensing module may be reduced, because there is no need to install additional optical lens. Thus, the sensitivity of the optical sensing module may be improved with the same light power.

The present disclosure is achieved by adopting a chip-on-board (COB) semiconductor assembly of the optical sensing module. The COB assembly includes separately mounting the image sensing element and the light emitting chip in proximity to each other on the substrate, or mounting an integrated circuit, which includes the optical sensing module and the light emitting chip integrated therein, on the substrate. Therefore, the dimension of the optical sensing module and the using area of the substrate can be reduced.

Accordingly, in the present disclosure, the optical sensing module includes the cover disposed on the substrate and the second light-transmitting portion disposed on the base of the laser pointing device, which is for screening reflected or scattered light to avoid the vertical movement generated from the vertical movement of the laser pointing device to interfere with the optical sensing module, and to have an excellent light pointing functionality and efficacy for a variety of working surfaces. The cover also provides the anti-vibration, anti-shock, and dust-proofing function that improves the reliability of the optical sensing module.

The aforementioned illustrations and following detailed descriptions are exemplary for the purpose of further explaining the scope of the present disclosure. Other objectives and advantages related to the present disclosure will be illustrated in the subsequent descriptions and appended drawings.

What is claimed is:

1. An optical sensing module, including:
an image sensing element including an optical sensor array and at least a control unit, wherein the sensor array is electrically connected to the control unit;
a light emitting chip, for providing a coherent light beam, wherein the light beam is reflected from an outside surface and to be received by the optical sensor array;
a substrate mounted with the image sensing element and the light emitting chip thereon; and
a cover is disposed on the substrate and to cover the image sensing element and the light emitting chip, wherein the cover having a first light-transmitting portion is disposed on a transmission path of the light beam for the transmission of the light beam.

2. The optical sensing module according to claim 1, wherein the light emitting chip is combined with the image sensing element to form an integrated circuit.

3. The optical sensing module according to claim 1, wherein the first light-transmitting portion is an opening.

4. The optical sensing module according to claim 1, wherein a ratio of the diameter of the first light-transmitting portion to the wavelength of the light beam is greater than 10.

5. The optical sensing module according to claim 1, wherein the light emitting chip is a laser diode die.

6. A laser pointing device, including:
an image sensing element including an optical sensor array and at least a control unit, wherein the sensor array is electrically connected to the control unit;
a light emitting chip, for providing a coherent light beam, wherein the light beam is reflected from an outside surface and to be received by the optical sensor array;
a substrate mounted with the image sensing element and the light emitting chip thereon;
a cover is disposed on the substrate and to cover the image sensing element and the light emitting chip, wherein the cover having a first light-transmitting portion is disposed on a transmission path of the light beam for the transmission of the light beam; and
a base having the substrate mounted thereon, and the cover is disposed between the base and the substrate, and wherein the base includes a second light-transmitting portion disposed on the transmission path of the light beam for the transmission of the light beam.

7. The laser pointing device according to claim 6, wherein the first light-transmitting portion is an opening.

8. The laser pointing device according to claim 6, wherein the second light-transmitting portion is an opening.

9. The laser pointing device according to claim 6, wherein a ratio of the diameter of the second light-transmitting portion to the wavelength of the light beam is greater than 10.

10. A method of manufacturing optical sensing module including the steps of:
applying a die attach process for mounting a laser diode die and an image sensing element on a substrate, the laser diode die is mounted on the substrate approximated to the image sensing element or the laser diode die is mounted on the image sensing element, wherein the image sensing element, the laser diode die and the substrate are electrically connected; and
fastening a cover on the substrate and covering the image sensing element and the laser diode die, wherein the cover has a first light-transmitting portion disposed on the transmission path of a light beam provided by the laser diode die.

11. The method of manufacturing optical sensing module according to claim 10, wherein the die attach process is a COB (Chip on Board) assembly process.

12. The method of manufacturing optical sensing module according to claim 10, wherein the die attach process including the steps of:
forming a bonding material on a surface of the substrate; and
fastening the laser diode die and the image sensing element on the bonding material, wherein the bonding material is directly bonded to the laser diode die and the image sensing element.

13. The method of manufacturing optical sensing module according to claim 10, wherein the die attach process including the steps of:
forming a first bonding material on a surface of the substrate;
fastening the image sensing element on the first bonding material, wherein the first bonding material is directly bonded to the image sensing element;
forming a second bonding material on a surface of the image sensing element; and
fastening the laser diode die on the second bonding material, wherein the second bonding material is directly bonded to the laser diode die.

14. The method of manufacturing optical sensing module according to claim 13, wherein after forming the first bonding material on the surface of the substrate, forming the second bonding material on the surface of the image sensing element.
